(19) United States
(12) Patent Application Publication
(10) Pub. No.: US 2007/0147123 A1
(43) Pub. Date: Jun. 28, 2007

(54) Split gate type non-volatile memory device and method of manufacturing the same

(75) Inventor: Chul Jin Yoon, Suwon-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/646,092

(22) Filed: Dec. 26, 2006

(30) Foreign Application Priority Data
Dec. 28, 2005 (KR) 10-2005-0132722

(51) Int. Cl. G11C 16/04

(52) U.S. Cl. 365/185.18

(57) ABSTRACT

There are provided a NOR-type non-volatile memory having a split gate and a method of manufacturing the same. The split gate includes a block that protrudes above a semiconductor substrate, a first electrode formed on one side wall of the block, an inter electrode dielectric layer formed on the block and the first electrode, and a second electrode formed on the inter electrode dielectric layer and extended from the top of the block to the side wall of the first electrode. The first electrodes are formed on the side walls of the block in the form of spacers. The plurality of blocks and first electrodes are formed in the direction of a word line to form a cell array.

This application claims the benefit of Korean Application No. 10-2005-0132722, filed on Dec. 28, 2005, which is incorporated by reference herein in its entirety.

### BACKGROUND OF THE INVENTION

1. Field of the Invention

The present invention relates to a semiconductor device and a method of manufacturing the same. More specifically, the present invention relates to a non-volatile memory device and a method of manufacturing the same.

2. Description of the Related Art

Since a non-volatile memory device can electrically erase and store data and can store data even if power is not supplied, the application thereof increases in various fields. The non-volatile memory device is divided into a NAND-type non-volatile memory device and a NOR-type non-volatile memory device. The NAND-type non-volatile memory device is used for storing data. The NOR-type non-volatile memory device is used for booting.

On the other hand, in the NOR-type non-volatile memory device, a plurality of memory cells that constitute a single transistor are connected to one bit line in parallel and only one memory cell transistor is connected between a drain connected to a bit line and a source region connected to a common source line. In the NOR-type non-volatile memory device, the current of a memory cell is high, the memory cell can operate at high speed, and the contact of the bit line and the common source line occupy a large area, so it is difficult to highly integrate the NOR-type non-volatile memory device.

In the NOR type non-volatile memory device, since the memory cells are connected to the bit line in parallel, when the threshold voltage of the memory cell transistor is lower than a voltage (commonly 0V) applied to the word line of a non-selected memory cell, current flows between a source and a drain regardless of whether a selected memory cell is turned on or off so that all of the memory cells read to be turned on. In order to solve such a problem, a non-volatile memory device referred to as a split gate type is introduced.

FIGS. 1A and 1B illustrate a NOR-type non-volatile memory device having a conventional split gate structure. FIG. 1A illustrates the top of a cell array in which a plurality of memory cells are arranged. FIG. 1B is a sectional view taken along the line I-I, that is, perpendicular to a word line. Referring to FIGS. 1A and 1B, a plurality of device isolation layers 20 are formed on a substrate to define an active region 10. A plurality of floating gates 16a are formed every unit cell on the active region 10 of the substrate and a control gate 32 that interposes an inter electrode dielectric layer 30 is formed on the plurality of floating gates 16a. The unit cells are connected to each other in parallel through a common source line 42. Here, reference numerals 52 and 50 denote a metal interconnection formed on the top and a contact, respectively. Transistor devices and the metal interconnection are insulated by an interlayer insulating layer.

Referring to FIGS. 1A and 1B, in the NOR-type non-volatile memory device having the conventional split gate structure, floating gates 16a that can trap electrons and selection gates 18 for selection transistors that prevent erroneous operation of excessive erase are serially connected to each other. Due to the addition of the selection transistors, the size of the unit cell increases. The channels of the selection transistors and storage transistors must be self-aligned with respect to the respective gates. It is necessary to secure margin in consideration of the manufacturing process ability of a device. Therefore, the size of a cell increases.

Also, in the non-volatile memory device, since electrons are injected into and removed from the floating gates to perform programming and erasing operations, the floating gate must be formed in each cell. In the conventional art, the floating gate is patterned using a hard mask. However, since a plurality of etching processes must be performed in this method, the number of processes increases. Also, a nitride layer is commonly used as the hard mask, it is difficult to etch the nitride layer. When the floating gate is formed, gap fill margin for forming a control gate must be considered. Also, the minimum margin for forming a common source line must be considered.

### SUMMARY OF THE INVENTION

The present invention has been made to solve the above problem(s), and therefore, it is an object of the present invention to provide a NOR-type non-volatile memory device of a split gate structure in which a cell area is significantly reduced. Also, it is another object of the present invention to a method of manufacturing a non-volatile memory device capable of forming a floating gate without using a hard mask.

According to one aspect of the present invention, there is provided a NOR-type non-volatile memory device having a split gate. The split gate includes a block that protrudes above a semiconductor substrate, a first electrode formed on one side wall of the block, an inter electrode dielectric layer formed on the block and the first electrode, and a second electrode formed on the inter electrode dielectric layer and extended from the top of the block to the side wall of the first electrode.

The first electrodes are formed on the side walls of the block in the form of spacers. The plurality of blocks and first electrodes are formed in the direction of a word line to form a cell array. Common source lines are formed along the blocks.

There is provided a method of manufacturing a NOR-type non-volatile memory having a split gate. The method includes the steps of (a) forming a protrusion extended in the direction of a word line on a semiconductor substrate, (b) forming a pair of conductive layer patterns extended in the direction of a word line on both side walls of the protrusion, (c) removing a part of the protrusion and the pair of conductive layer patterns to form a plurality of blocks and first electrode pairs separated from each other in the direction of a word line, and (d) sequentially forming an inter electrode dielectric layer and a second electrode on the plurality of blocks and first electrode pairs.

After forming the protrusion on a substrate, a plurality of device isolation layers that define the active region of the substrate can be formed on both sides of the protrusion. After forming the device isolation layer, a tunnel oxide layer is formed in the active region of the substrate and on the external wall of the protrusion. The pair of first conductive layer patterns are formed on both side walls of the protrusion in the form of spacers. The common source lines are extended along the plurality of blocks.

### BRIEF DESCRIPTION OF DRAWINGS

FIG. 1A illustrates the top of a NOR-type non-volatile memory device having a conventional split gate structure and FIG. 1B is a sectional view taken along the line I-I of FIG. 1A;

FIGS. 2A to 2C are sectional views perpendicular to the direction of a word line that illustrate a method of manufacturing a non-volatile memory device having a split gate structure according to the present invention; and

FIG. 3 is a perspective view illustrating silicon blocks and floating gates formed through a bit line etching process.

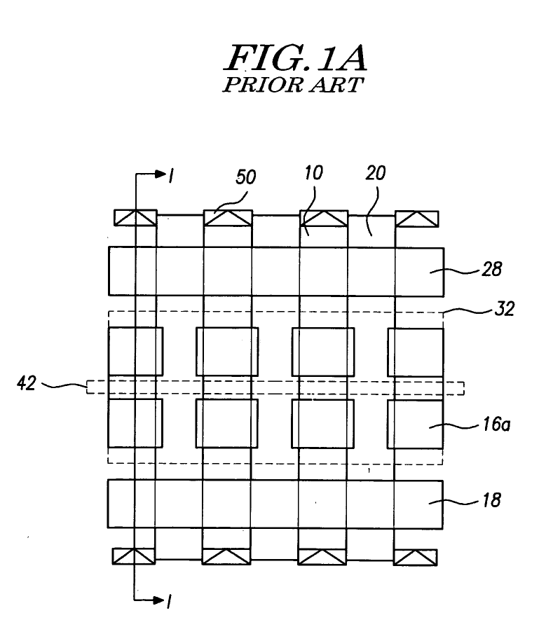

### DETAILED DESCRIPTION OF THE INVENTION

Preferred embodiments of a NOR-type non-volatile memory device of a split gate structure according to the present invention and a method manufacturing the same will be described with reference to the attached drawings.

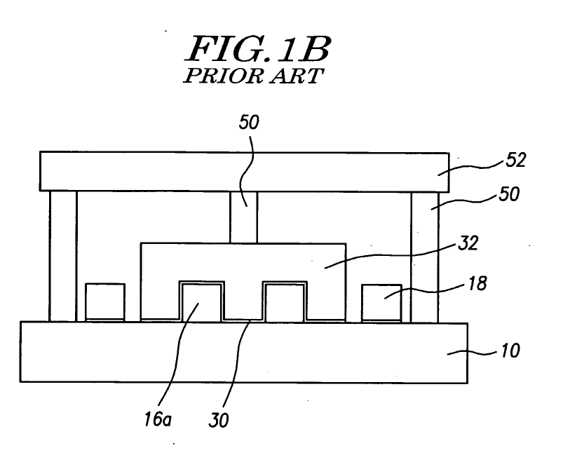

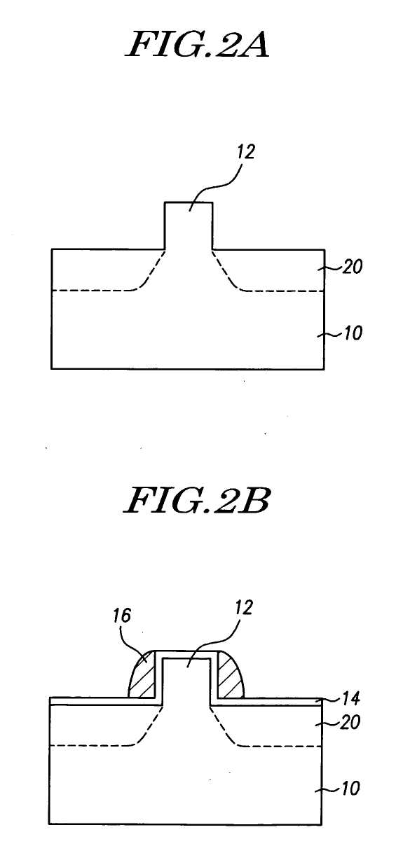

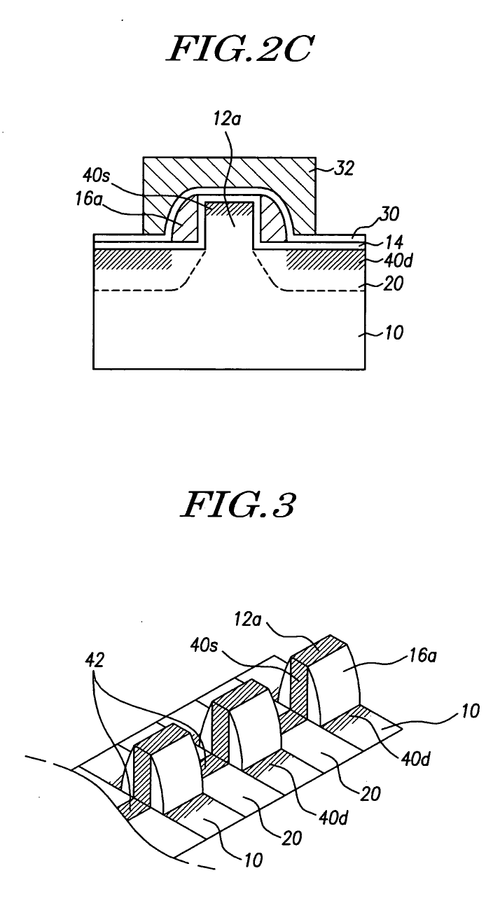

Referring to FIG. 2A, a protrusion 12 of predetermined height is formed on a silicon substrate 10. The protrusion 12 can be formed by etching the substrate 10. The protrusion 12 is extended in the direction of a word line. Then, a plurality of device isolation layer 20 that define an active region are formed on both sides of the protrusion 12. The device isolation layer 20 is formed in a field region adjacent to the active region (refer to FIG. 3).

On the other hand, the device isolation layer 20 is preferably formed after forming the protrusion 12 on the substrate through a common device isolation layer process such as shallow trench isolation (STI) process. The, device isolation layer 20 is divided on both sides due to the protrusion 12. When the STI is formed, the STI oxide layer formed in a trench is removed to coincide with the surface of the substrate 10 where the protrusion 12 is not formed through a wet etching process.

Then, the threshold voltage of a cell is controlled by performed a photolithography process and an ion injection process on the active region of the substrate 10.

Then, after depositing polysilicon on the entire surface of the substrate 10, the photolithography process and an etching process are performed to form first conductive patterns 16. At this time, the first conductive layer patterns are formed through an etch back process without a mask. Therefore, the first conductive patterns 16 are formed on the side walls of the protrusion 12 in the form of spacers. Since a mask is not used when the first conductive layer patterns 16, it is not necessary to use expensive exposure equipment like in the conventional photolithography process. Also, in the conventional art, a method of forming a floating gate of a fine line width using a hard mask instead of the expensive exposure equipment. However, according to the present invention, it is not necessary to use the hard mask. Also, in the floating gate where the first conductive layer patterns 16 are in the form of spacers, a process variable in the etching process is controlled so that the floating gate has the minimum line width. Therefore, a cell area is significantly reduced. Due to the protrusion 12, short with an adjacent cell is prevented.

Before forming the first conductive pattern 16, the active region of the substrate is oxidized to form an oxide layer. At this time, the external wall of the protrusion 12 is oxidized to form a tunnel oxide layer 14.

Then, the protrusion 12 and the first conductive layer patterns 16 in the form of spacers are patterned by a bit line etching process. Referring to FIG. 3, the patterned protrusion 12 and the first conductive layer patterns 16 are divided into silicon blocks 12a and first electrodes 16a. Therefore, the plurality of silicon blocks 12a in the direction of a word line and the plurality of first electrode pairs 16a that face each other on both side walls of the silicon blocks 12a so that two floating gates form a group to form a cell array. Then, as illustrated in FIG. 3, when dopant is ion injected into the active region 10 of the substrate, common source regions and common source lines are simultaneously formed along the plurality of silicon blocks 12a.

In particular, in FIG. 3, common sources 40s are formed in the regions marked with oblique lines on the top and front and rear side walls of the silicon blocks 12a and source lines 42 are formed in a substrate region a part of which is removed to be exposed by the bit line etching process. Drain regions 40d are formed by the dopant implanted into the substrate region on the right or left of the first electrodes 16a.

On the other hand, in the conventional art, a self-aligned source (SAS) of removing the STI oxide layer using the etching selectivity of polysilicon, silicon, and an oxide layer is used. However, according to the present invention, it is not necessary to use the SAS technology.

Then, as illustrated in FIG. 2C, an inter electrode dielectric layer 30 is formed on the entire surface of the substrate. Then, polysilicon is deposited on the inter electrode dielectric layer 30 and is patterned to form a second electrode 32 that forms the control gate. The second electrode 32 is formed to completely cover the silicon block 12a and the first electrode pairs 16a. Also, as illustrated in FIG. 2C, the common source region 40s is formed on the top of the silicon block 12a. The source regions are formed on the front and rear side walls of the silicon block 12a but are not shown in FIG. 2C in convenience sake.

According to the present invention a symmetrical floating gate can be formed to have a fine line width through the etch back process. Therefore, since it is not necessary to use expensive exposure equipment or a hard mask, manufacturing processes are relatively simple. Also, the area of a unit cell can be minimized. Also, it is not necessary to perform the complicated SAS process in order to form the common source lines. As a result, it is possible to reduce the manufacturing cost of a device and to maximize the effect of the manufacturing processes.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A non-volatile split gate memory device comprising:
a block above a semiconductor substrate;
a first electrode on one sidewall of the block;
an inter-electrode dielectric layer on the block and the first electrode; and
a second electrode on the inter electrode dielectric layer and extending from a top of the block to the sidewall of the first electrode.

2. The non-volatile memory device of claim 1, comprising a NOR-type flash memory device.

3. The non-volatile memory device of claim 1, wherein the first electrode comprises a sidewall spacer.

4. A non-volatile memory, comprising a plurality of the split-gate devices of claim 1, wherein the blocks and the first electrodes are aligned in a direction of a word line to form a cell array.

5. The non-volatile memory device of claim 4, further comprising a common source line between two adjacent rows of blocks.

6. The non-volatile memory device of claim 1, further comprising a plurality of device isolation layers that define an active region of the substrate on opposite sides of the block.

7. A method of manufacturing a non-volatile memory having a split gate, the method comprising the steps of:
forming a protrusion from a semiconductor substrate, extending in a word line direction;
forming a conductive layer on sidewalls of the protrusion;
removing a part of the protrusion and the conductive layer to form a plurality of blocks and first electrode pairs separated from each other in a direction of a word line; and
sequentially forming an inter-electrode dielectric layer and a second electrode on the plurality of blocks and first electrode pairs.

8. The method of claim 7, further comprising the step of forming a plurality of device isolation layers that define the active region of the substrate on opposite sides of the protrusion after forming the protrusion.

9. The method of claim 8, further comprising the step of forming a tunnel oxide layer in an active region of the substrate and on the external surfaces of the protrusion after forming the device isolation layer.

10. The method of claim 9, wherein forming the conductive layer comprises depositing the conductive layer on the tunnel oxide layer, and anisotropically etching the conductive layer to form conductive sidewall spacers.

11. The method of claim 7, further comprising the step of ion injecting a dopant into the substrate to form a common source line along the blocks.

12. A non-volatile split gate memory device comprising:
a plurality of blocks extending from a semiconductor substrate and aligned in a word line direction;
a tunnel oxide layer on top and sidewall surfaces of each block;
a pair of first electrodes on the tunnel oxide layer, on opposite sidewalls of each block;
an inter-electrode dielectric layer on each pair of first electrodes; and
a second electrode on each inter-electrode dielectric layer, over the top surface of the block and the pair of first electrodes.

13. A non-volatile memory array, comprising a plurality of the devices of claim 12, arranged as a plurality of rows and columns.

14. The non-volatile memory array of claim 13, comprising a NOR-type flash memory.

15. The non-volatile memory device of claim 12, wherein the pair of first electrodes comprise sidewall spacers.

16. The non-volatile memory device of claim 12, further comprising a common source line in the blocks, between the pair of first electrodes.

17. The non-volatile memory device of claim 16, wherein the common source line comprises an ion implant region.

18. The non-volatile memory device of claim 17, wherein a same or different ion implant region electrically connects common source lines in adjacent blocks.

19. The non-volatile memory device of claim 12, further comprising a plurality of device isolation layers on opposite sides of the blocks, the device isolation layers defining an active region of the substrate.
